(19) United States
(12) Patent Application Publication
(10) Pub. No.: US 2026/0090435 A1
(43) Pub. Date: Mar. 26, 2026

(54) SELECTIVE POROUS GLASS FOR GLASS SUBSTRATE SINGULATION

(71) Applicant: Intel Corporation, Santa Clara, CA (US)

(72) Inventors: Brandon C. MARIN, Gilbert, AZ (US); Hiroki TANAKA, Gilbert, AZ (US); Jeremy D. ECTON, Gilbert, AZ (US); Srinivas Venkata Ramanuja PIETAMBARAM, Chandler, AZ (US); Gang DUAN, Chandler, AZ (US)

(21) Appl. No.: 18/895,170

(22) Filed: Sep. 24, 2024

(51) Int. Cl. H01L 23/15; H01L 23/538

(52) U.S. Cl. CPC H10W 70/692; H10W 70/611; H10W 70/635

(57) ABSTRACT

Embodiments disclosed herein include an apparatus that includes a substrate that includes a glass layer. In an embodiment, a first region of the substrate has a first porosity and a second region of the substrate has a second porosity that is higher than the first porosity. In an embodiment, the second region is at an edge of the substrate. In an embodiment, the substrate further includes a via that passes through a thickness of the substrate.

### BACKGROUND

Electronics packaging substrates may include a core. Existing core materials include organic dielectrics that comprise fiber reinforcement materials. As devices continue to scale in complexity, alternative core materials are desired. For example, package cores that include solid glass layers may be one potential option. Glass cores enables stiffer substrates, flatter surfaces, and improved dimensional stability.

However, glass substrates that are used for the core are more fragile than existing organic core materials. Singulation of glass core substrates into individual units can be particularly problematic. For example, conventional mechanical singulation processes may result in defect generation (e.g., cracks, seware defects, etc.) as well as dielectric delamination.

### BRIEF DESCRIPTION OF THE DRAWINGS

FIG. 1A is a cross-sectional illustration of a glass core substrate with a first region with a low porosity and a second region with a high porosity that surrounds the first region, in accordance with an embodiment.

FIG. 1B is a cross-sectional illustration of a glass core substrate with a first region with a low porosity and a second region with a high porosity that surrounds the first region where an edge of the second region is sloped, in accordance with an embodiment.

FIG. 1C is a cross-sectional illustration of a glass core substrate with a first region with a low porosity and a second region with a high porosity that surrounds the first region where an edge of the second region has a double slope, in accordance with an embodiment.

FIG. 1D is a cross-sectional illustration of a glass core substrate with a first region with a low porosity and a second region with a high porosity that surrounds the first region where an interface between the first region and the second region is curved, in accordance with an embodiment.

FIG. 2A is a cross-sectional illustration of a package substrate with a glass core substrate and buildup layer with a sloped edge, in accordance with an embodiment.

FIG. 2B is a cross-sectional illustration of a package substrate with a glass core substrate and buildup layer with a vertical edge, in accordance with an embodiment.

FIGS. 3A-3E are cross-sectional illustrations depicting a process for singulating a package substrate with a glass core substrate that includes a porous region within a saw street, in accordance with an embodiment.

FIGS. 4A and 4B are cross-sectional illustrations depicting a process for singulating a package substrate with a glass core substrate that includes a porous region within a saw street, in accordance with an additional embodiment.

FIG. 5 is a flow diagram describing a process for singulating a package substrate with a glass core substrate that includes a porous region within a saw street, in accordance with an additional embodiment.

FIG. 6 is a cross-sectional illustration of an electronic system that comprises a package substrate with a glass core substrate with a first region and a porous second region surround the first region, in accordance with an embodiment.

FIG. 7 is a schematic of a computing device built in accordance with an embodiment.

### EMBODIMENTS OF THE PRESENT DISCLOSURE

Described herein are package substrates that include a glass core substrate with an outer ring that is more porous than a bulk of the glass core substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, glass substrates used for package cores provides multiple advantages compared to organic dielectric substrates. For example, glass core substrates may be stiffer, have flatter surfaces, and improved dimensional stability. However, the singulation process used in existing package substrate assembly flows may use a mechanical sawing process. Such mechanical sawing is not compatible with glass substrates since the sawing can lead to cracking, seware defects, dielectric delamination, and/or other damage to the glass substrate. As such, device yields are low.

Accordingly, embodiments disclosed herein may include a singulation process that leverages selectively formed high porosity regions within the glass core substrates in order to locally weaken the glass along the saw streets. The weaker regions of the glass may be more easily ablated with a laser ablation process. As such, damage to the resulting glass core substrates is reduced. In an embodiment, the glass core substrate may be locally modified to increase porosity through the application of a wet etching chemistry to selected regions. The wet etching chemistry may be tuned to attack more amorphous regions of the glass core substrate. This will generate a lattice-like structure with voids and/or gaps that lead to the high porosity.

In an embodiment, localized porosity changes and laser ablation based singulation may result in the formation of distinctive structures in the overall package substrate. For example, residual portions of the high porosity regions may persist after the singulation process. As such, a ring or frame of high porosity glass may be provided around a bulk region of glass that has a low porosity. Further, the edge profile of the glass core substrate may indicate the use of a laser ablation process or the like. For example, the glass core substrate may include an edge that has a tapered profile.

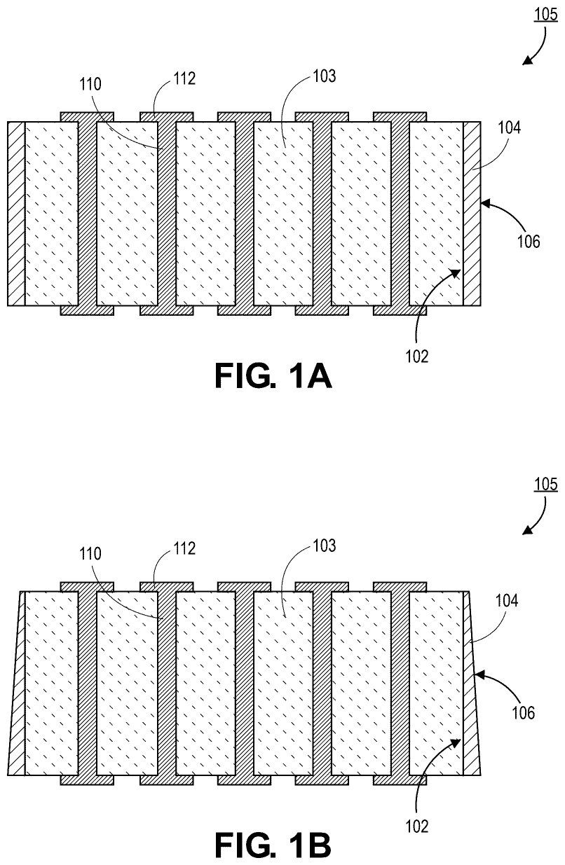

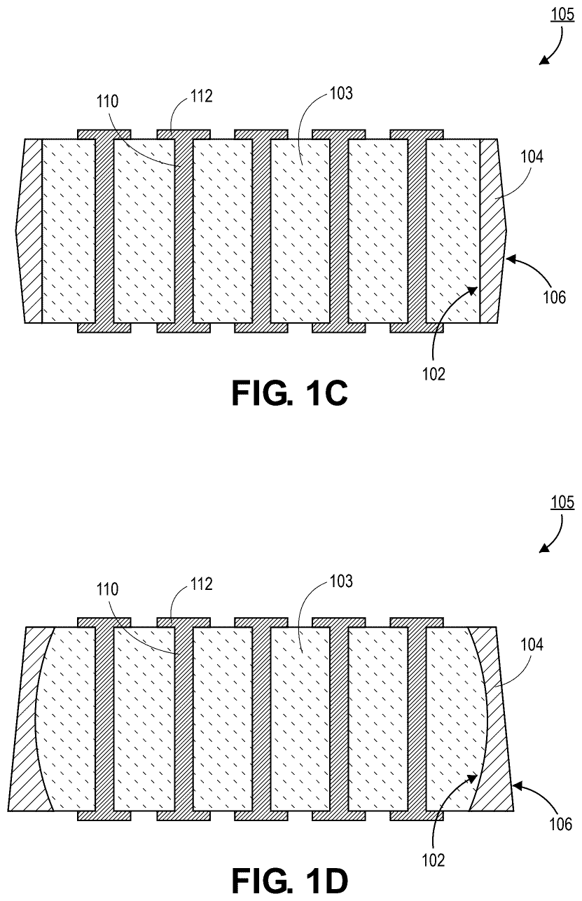

Referring now to FIGS. 1A-1D, a series of cross-sectional illustrations depicting various glass core substrate 105 architectures is shown, in accordance with various embodiments. These glass core substrates 105 may be integrated into package substrates. As such, package substrates that are able to be singulated easily may also take advantage of the benefits provided by the use of a glass core substrate 105.

Referring now to FIG. 1A, a cross-sectional illustration of a portion of a glass core substrate 105 is shown, in accordance with an embodiment. In an embodiment, the glass core substrate 105 may be substantially all glass. The glass core substrate 105 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, the glass core substrate 105 may be distinguished from, for example, the “prepreg” or “FR4” core of a Printed Circuit Board (PCB) substrate which typically comprises glass fibers embedded in a resinous organic material, such as an epoxy.

The glass core substrate 105 may have any suitable dimensions. In a particular embodiment, the glass core substrate 105 may have a thickness that is approximately 50 μm or greater. For example, the thickness of the glass core substrate 105 may be between approximately 50 μm and approximately 1.4 mm. Though, smaller or larger thicknesses may also be used. The glass core substrate 105 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core substrate 105 (from an overhead plan view) may be between approximately 10 mm×10 mm and approximately 250 mm×250 mm. In an embodiment, the glass core substrate 105 may have a first side that is perpendicular or orthogonal to a second side. In a more general embodiment, the glass core substrate 105 may comprise a rectangular prism volume with sections (e.g., vias) removed and filled with other materials (e.g., metal, etc.).

The glass core substrate 105 may comprise a single monolithic layer of glass. In other embodiments, the glass core substrate 105 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core substrate 105 may each have a thickness less than approximately 50 μm. For example, discrete layers of glass in the glass core substrate 105 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core substrate 105 may be any suitable glass formulation that has the necessary mechanical robustness and compatibility with semiconductor packaging manufacturing and assembly processes. For example, the glass core substrate 105 may comprise aluminosilicate glass, borosilicate glass, alumino-borosilicate glass, silica, fused silica, or the like. In some embodiments, the glass core substrate 105 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core substrate 105 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core substrate 105 may comprise at least 23 percent silicon (by weight) and at least 26 percent oxygen (by weight). In some embodiments, the glass core substrate 105 may further comprise at least 5 percent aluminum (by weight).

In an embodiment, the glass core substrate 105 may comprise one or more electrically conductive vias 110 that pass through a thickness of the glass core substrate 105. In the illustrated embodiment, the vias 110 have substantially vertical sidewalls. Though, in other embodiments, the sidewalls of the vias 110 may be sloped. For example, the vias 110 may have a tapered cross-sectional shape, or the vias 110 may have an hourglass shaped cross-section. Pads 112 may be provided over and/or under the vias 110. In an embodiment, the vias 110 and the pads 112 may comprise copper or any other suitable electrically conductive material.

In an embodiment, the glass core substrate 105 may comprise a first region 103 and a second region 104. The first region 103 and the second region 104 may both comprise a glass layer. In some instances, the material composition of the first region 103 may be similar to the material composition of the second region 104. However, the first region 103 and the second region 104 may have different porosities. More generally, the first region 103 may have a lower porosity than the second region 104. With respect to glass layers described herein, “porosity” may refer to a percentage of a cross-sectional section of the glass layer that is non-solid (e.g., an air gap, a void, etc.). Stated differently, if a cross-sectional section of a glass layer has a total area of 1.0 mm² and 0.5 mm² of the total area comprises a void, then the porosity of the cross-sectional section of the glass layer may be 50%. In an embodiment, the first region 103 may have a porosity of 0% to approximately 30%, and the second region 104 may have a porosity of approximately 20% to approximately 99%. Though, the second region 104 may have higher or lower porosities in some embodiments.

The presence of the porous second region 104 at the edges of the first region 103 provides several benefits. For example, the higher porosity of the second region 104 may enable simpler singulation processes from a panel form factor. Such a singulation process will also impart less damage to the first region 103, which may form a bulk (i.e., majority) of the glass core substrate 105. The residual second region 104 may also form a buffer region to the first region 103 during downstream process. For example, the high porosity may result in a region that deforms without the generation of cracks that can propagate through the first region 103. As such, the resulting glass core substrate 105 may be more robust than existing glass core solutions.

As shown in FIG. 1A, the second region 104 is provided along both edges of the first region 103. In some embodiments, the second region 104 may surround an entire perimeter of the first region 103. For example, the second region 104 may be a frame that surrounds the first region 103. Though, other embodiments may include a second region 104 that partially surrounds a perimeter of the first region 103.

In the illustrated embodiment, the second region 104 may extend from a top surface of the glass core substrate 105 to a bottom surface of the glass core substrate 105. Other embodiments may include a second region 104 that passes only partially through a thickness of the glass core substrate 105. In one such embodiment, the second region 104 may extend from a top surface of the glass core substrate 105 partially through a thickness of the glass core substrate 105 so that a portion of the first region 103 is provided below the second region 104. In another such embodiment, the second region 104 may extend from the top surface of the glass core substrate 105 and the bottom surface of the glass core substrate 105. However, a portion of the first region 103 may be provided across a width of the second region 104. That is, the second region 104 may comprise a discrete upper portion and lower portion with the first region 103 between the upper portion and the lower portion.

In an embodiment, an interface 102 between the first region 103 and the second region 104 may have any profile. In FIG. 1A, the interface 102 has a vertical profile. That is, the interface 102 may be substantially orthogonal to a top and/or bottom surface of the glass core substrate 105. The profile of the interface 102 may be dictated by the process used to form the localized porosity in the glass core substrate 105. Examples of different profiles for the interface 102 are described in greater detail herein. It is to be appreciated that the interface 102 may not be a clearly discernable boundary due to the diffusive nature of the process used to form the high porosity second region 104 (e.g., a wet etching process). For example, the interface 102 may be a gradient in the change of porosity from a first low porosity (of the first region 103) to a second high porosity (of the second region 104).

In an embodiment, an outer edge 106 of the glass core substrate 105 (which may be the outer edge of the second region 104) may also have different profiles depending on the process used to singulate the glass core substrate 105 from a larger panel. In the embodiment shown in FIG. 1A, the edge 106 may have a substantially vertical profile. In some embodiments, the edge 106 may be substantially parallel to the interface 102.

In an embodiment, the second region 104 may have any width. That is, the second region 104 may extend into the glass core substrate 105 (from the edge 106) any suitable distance. For example, a distance from the edge 106 to the interface 102 (in a direction parallel to a top surface of the glass core substrate 105) may be up to approximately 1.0 μm, up to approximately 5.0 μm, up to approximately 10 μm, up to approximately 25 μm, or up to approximately 50 μm.

Referring now to FIG. 1B, a cross-sectional illustration of a glass core substrate 105 is shown, in accordance with an additional embodiment. In an embodiment, the glass core substrate 105 in FIG. 1B may be similar to the glass core substrate 105 in FIG. 1A, with the exception of the second region 104. Instead of having a second region 104 that includes a substantially uniform width between the bottom surface and the top surface of the glass core substrate 105, the width of the second region 104 is variable from top to bottom. For example, an upper end of the second region 104 is narrower than a bottom end of the second region 104 (as viewed in FIG. 1B). That is, the profile of the edge 106 may be non-vertical with respect to a top and/or bottom surface of the glass core substrate 105.

In the illustrated embodiment, the second region 104 may extend from the top surface of the glass core substrate 105 to the bottom surface of the glass core substrate 105. In other embodiments, the profile of the edge 106 may be such that the edge 106 intersects the interface 102 before reaching the top surface of the glass core substrate 105. In such an embodiment, an outer edge of the first region 103 may be exposed in the glass core substrate 105.

As will be described in greater detail below, the singulation process may include a laser ablation process. The laser ablation process may form a trench in the second region 104 that has tapered sidewalls. When the singulation is complete, the opposite edge of second region 104 of the trench remains on an adjacent glass core substrate 105 (not shown in FIG. 1B), and the residual second region 104 may have an edge with a single slope.

Referring now to FIG. 1C, a cross-sectional illustration of a glass core substrate 105 is shown, in accordance with an additional embodiment. In an embodiment, the glass core substrate 105 in FIG. 1C may be similar to the glass core substrate 105 in FIG. 1B, with the exception of the second region 104. Instead of having a single slope for the edge 106, the edge 106 may have two or more slopes. For example, the edge 106 may have two slopes that meet each other at a point. The point may be provided at an approximate midpoint between the top surface and the bottom surface of the glass core substrate 105. Other embodiments may include a point that is provided at any height between the top surface and the bottom surface of the glass core substrate 105.

In an embodiment, such a double sloped edge 106 for the second region 104 may be formed through the use of a double sided singulation process. For example, a first laser may be pointed at a top surface of the second region 104 and a second laser may be pointed at a bottom surface of the second region 104. A double laser singulation process may allow for faster singulation in some embodiments.

Referring now to FIG. 1D, a cross-sectional illustration of a glass core substrate 105 is shown, in accordance with an additional embodiment. In an embodiment, the glass core substrate 105 in FIG. 1D may be similar to the glass core substrate 105 in FIG. 1B, with the exception of the interface 102. Instead of an interface 102 that is substantially vertical, the interface 102 may be non-vertical. In the particular embodiment shown in FIG. 1D, the interface 102 is non-planer (e.g., curved). For example, a top and bottom of the first region 103 may be narrower than a midpoint (in the vertical direction) of the first region 103.

In an embodiment, such curved interfaces 102 may be the result of the process used to form the porous second regions 104. For example, when a wet etching process is used to form the second regions 104, the etchant may be isotropic in nature. This can result in the area proximate to the top surface and the bottom surface of the glass core substrate 105 having a greater width since the etching spreads laterally in addition to diffusing in the vertical direction. In the embodiment shown in FIG. 1D, a double sided wet etch is used. If a single sided wet etch were used, the curved interface may appear different than what is shown in FIG. 1D. That is, the surface of the glass core substrate 105 that is exposed to the wet etchant may have a second region 104 with a width at the exposed surface of the glass core substrate 105 that is greater than a width at the non-exposed surface of the glass core substrate 105.

In an embodiment, the edge 106 shown in FIG. 1D is similar to the edge shown in FIG. 1B (i.e., the edge 106 has a single slope). Though, in other embodiments, the edge 106 may have any of the profiles described herein (e.g., vertical, double sloped, or the like).

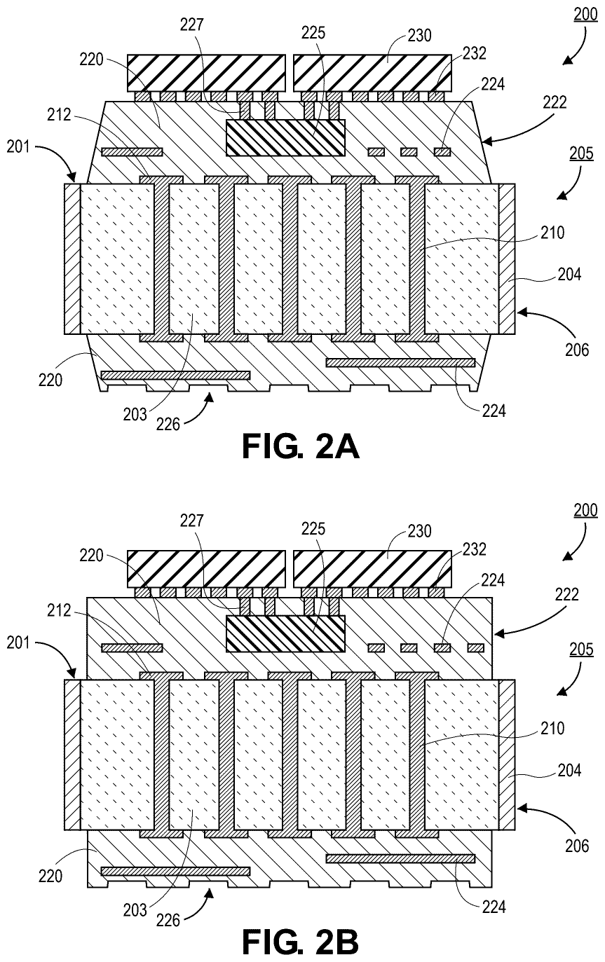

Referring now to FIGS. 2A and 2B, cross-sectional illustrations of package substrates 200 that include glass core substrate 205 are shown, in accordance with various embodiments. In FIGS. 2A and 2B, the glass core substrate 205 is similar to the glass core substrate 105 shown in FIG. 1A. For example, the glass core substrate 205 may comprise a first region 203 that is surrounded by a high porosity second region 204. The edge 206 of the second region 204 may be vertical or have any other profile. Similarly, the interface between the first region 203 and the second region 204 may have any suitable profile. Vias 210 with overlying pads 212 may pass through a thickness of the low porosity first regions 203. Though, it is to be appreciated that glass core substrates 205 may be similar to any of the glass core substrates described in greater detail herein.

Referring now to FIG. 2A, a cross-sectional illustration of a package substrate 200 is shown, in accordance with an embodiment. In an embodiment, the package substrate 200 may comprise buildup layers 220 over and/or under the glass core substrate 205. The buildup layers 220 may comprise organic buildup film or the like. For example, a plurality of buildup film layers may be laminated over each other in order to form the buildup layers 220. In an embodiment, electrically conductive routing (e.g., pads 212, vias 227, traces 224, and/or the like) may be embedded in and/or provided on the buildup layers 220. In an embodiment, the bottom buildup layer 220 may comprise openings 226 to accommodate second level interconnects (SLIs) (not shown in FIG. 2A).

In an embodiment, a bridge 225 may also be embedded within the buildup layers 220. The bridge 225 may be a glass substrate, a semiconductor substrate, or the like that comprises electrically conductive routing (not shown) to electrically couple two or more dies 230 together. For example, vias 227 may electrically couple first level interconnects (FLIs) 232 from the dies 230 to the bridge 225. As such, an electrically conductive path that passes through and/or on the bridge 225 may be provided between a first die 230 and a second die 230.

In an embodiment, the buildup layers 220 may have edges 222 that have a sloped profile relative to a top and/or bottom surface of the glass core substrate 205. The sloped edges 222 may be the result of the patterning process used during singulation in order to expose the second regions 204, as will be described in greater detail herein. For example, sloped edges 222 may be the result of a laser ablation process.

In an embodiment, a width of the glass core substrate 205 may be greater than a width of the buildup layers 220. Stated differently, the edges 222 may be offset back from the edge 206 of the second region 204. For example, top and/or bottom surfaces 201 of the glass core substrate 205 may be exposed in the package substrate 200. In the illustrated embodiment the exposed surfaces 201 comprise portions of both the first region 203 and the second region 204 of the glass core substrate 205. Other embodiments may include surfaces 201 that only comprise the second region 204 of the glass core substrate 205.

Referring now to FIG. 2B, a cross-sectional illustration of a package substrate 200 is shown, in accordance with an additional embodiment. The package substrate 200 in FIG. 2B may be similar to the package substrate 200 in FIG. 2A, with the exception of the profile of the edges 222 of the buildup layers 220. Instead of having a sloped profile, the edges 222 may have a substantially vertical profile. A vertical profile for the edges 222 may be generated through a drilling process, an anisotropic etching process, or the like.

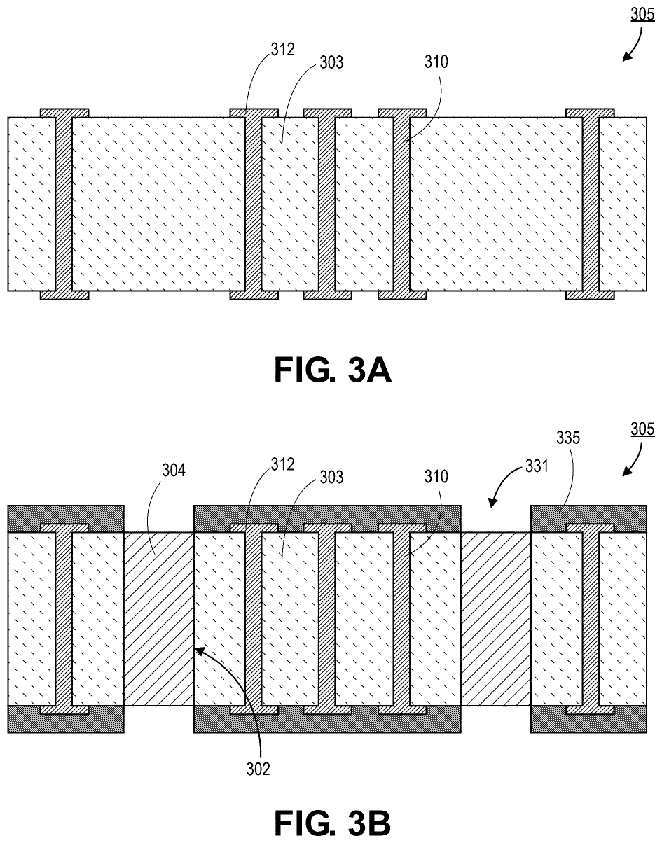

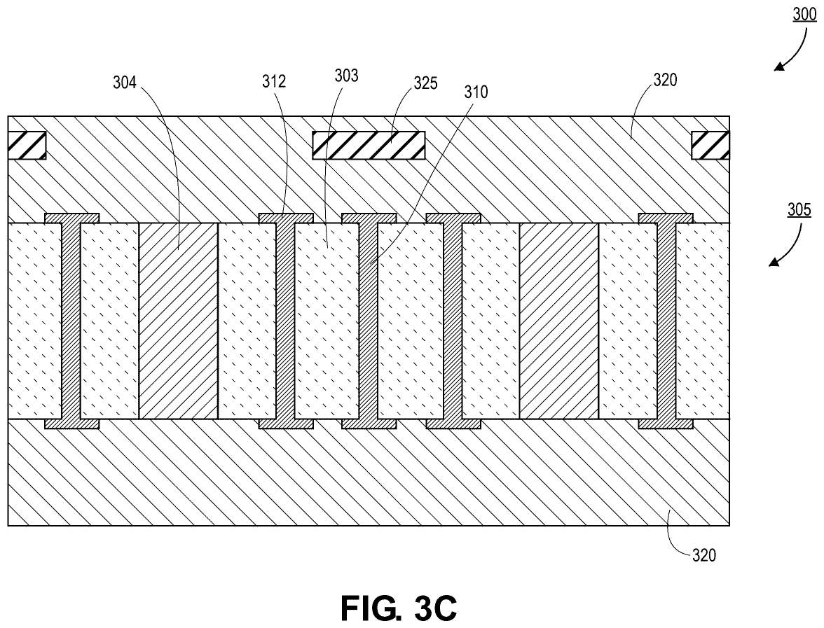

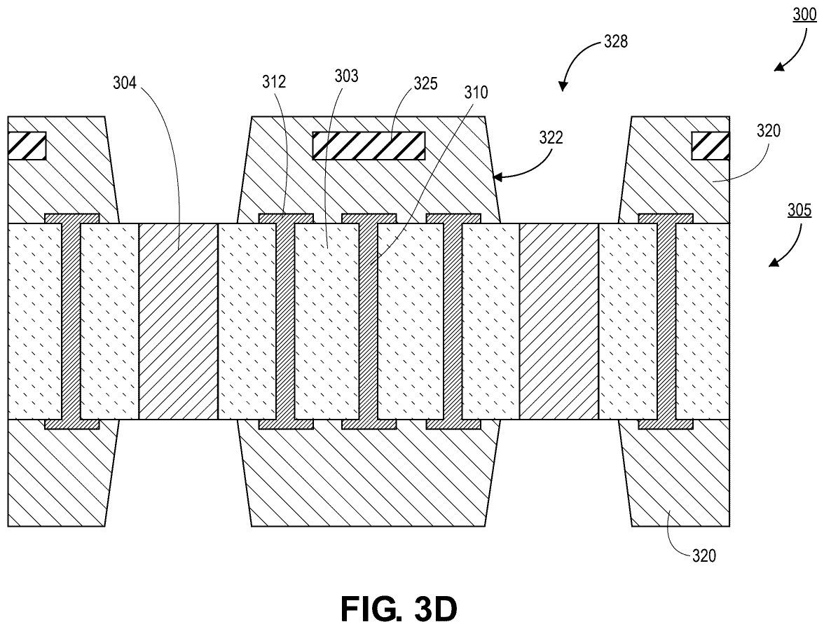

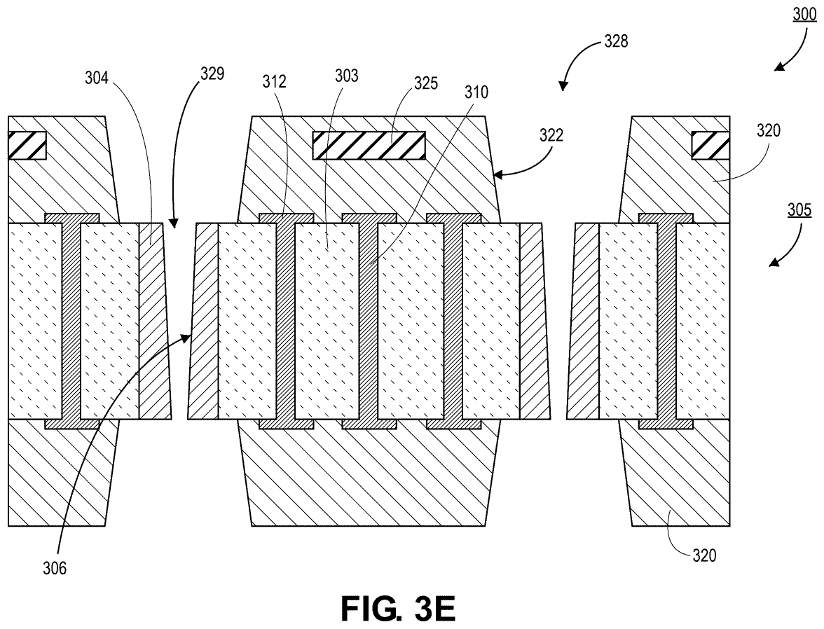

Referring now to FIGS. 3A-3E, a series of cross-sectional illustrations depicting a process for forming a package substrate 300 with a glass core substrate 305 that is singulated from a panel along a high porosity region is shown, in accordance with an embodiment.

Referring now to FIG. 3A, a cross-sectional illustration of a glass core substrate 305 is shown, in accordance with an embodiment. In an embodiment, the glass core substrate 305 may be similar to any of the glass core substrates described in greater detail herein. In an embodiment, vias 310 with overlying pads 312 may be formed through a thickness of the glass core substrate 305. In the embodiment shown, a panel level glass core substrate 305 is shown. For example, the middle three vias 310 may ultimately be part of a single package substrate 300 unit, and the two outer vias 310 may be part of two different package substrate 300 units. In an embodiment, the glass core substrate 305 may comprise a first region 303. The first region 303 may have a first porosity that is relatively low.

Referring now to FIG. 3B, a cross-sectional illustration of the glass core substrate 305 after second regions 304 with a high porosity are formed in the glass core substrate 305 is shown, in accordance with an embodiment. In an embodiment, the second regions 304 may be formed with a wet etching process that selectively removes amorphous portions of the glass material. This may leave behind a porous network of glass in the second regions 304. In an embodiment, the etchant may comprise potassium hydroxide (KOH), sodium hydroxide (NaOH), or the like. In an embodiment, a porosity of the second regions 304 may be approximately 20% to approximately 99%. Though, the second region 304 may have higher or lower porosities in some embodiments.

In an embodiment, the etchant is selectively applied to glass core substrate 305 through the use of a mask 335 that is provided over the top and bottom surfaces of the glass core substrate 305. In an embodiment, openings 331 may be provided in the masks 335 in locations where saw streets are desired. In the illustrated embodiment, the interfaces 302 between the first regions 303 and the second regions 304 are shown as being substantially vertical. Though, curved interfaces 302 or any other interface profile described herein may be provided between the first regions 303 and the second regions 304. Additionally, while the second region 304 is shown through an entire thickness of the glass core substrate 305, other embodiments may include a second region 304 that only partially extends through a thickness of the glass core substrate 305.

Referring now to FIG. 3C, a cross-sectional illustration of a portion of a package substrate 300 that is formed with the glass core substrate 305 is shown, in accordance with an embodiment. In an embodiment, the masks 335 may be removed after the formation of the second regions 304, and buildup layers 320 may be provided over and/or under the glass core substrate 305. In an embodiment, the buildup layers 320 may comprise laminated layers of organic buildup film or the like. Electrically conductive routing (not shown) may also be fabricated within the buildup layers 320. In some embodiments, a bridge 325 may be embedded within the buildup layers 320 as well.

Referring now to FIG. 3D, a cross-sectional illustration of a portion of the package substrate 300 after openings 328 are formed through the buildup layers 320 are formed is shown, in accordance with an embodiment. In an embodiment, the openings 328 may expose surfaces of the glass core substrate 305. In some embodiments, the openings 328 may expose at least a portion of the second regions 304. The openings 328 may also expose a portion of the first region 303 in some embodiments. That is, the openings 328 may be provided over the second regions 304 in some embodiments. As shown, the openings 328 may have sloped sidewalls 322. Sloped sidewalls 322 may be the result of a laser ablation process or the like.

Referring now to FIG. 3E, a cross-sectional illustration of the package substrate 300 after openings 329 are formed through the second regions 304 is shown, in accordance with an embodiment. In an embodiment, the openings 329 through the second regions 304 may be formed with a laser ablation process or the like. In the case of a single sided laser ablation, the edge 306 of the second regions 304 may be sloped. Though, the edge 306 may have any suitable profile, such as any of those described herein, depending on the process used to form the openings 329.

In an embodiment, the high porosity of the second regions 304 allows for easier laser ablation singulation of the package substrates 300. For example, lower laser power may be necessary and/or the duration of the singulation process may be reduced. The lower intensity used for the laser ablation singulation process prevents or minimizes damage that is transferred into the first region 303 of the glass core substrate 305. As such, the resulting package substrate 300 has better robustness and is less prone to crack propagation within the first region 303 of the glass core substrate 305.

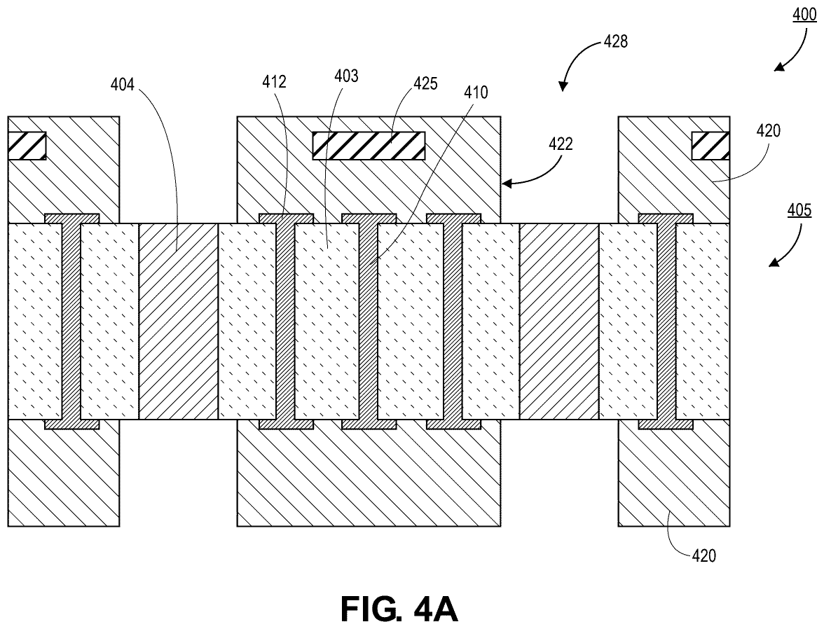

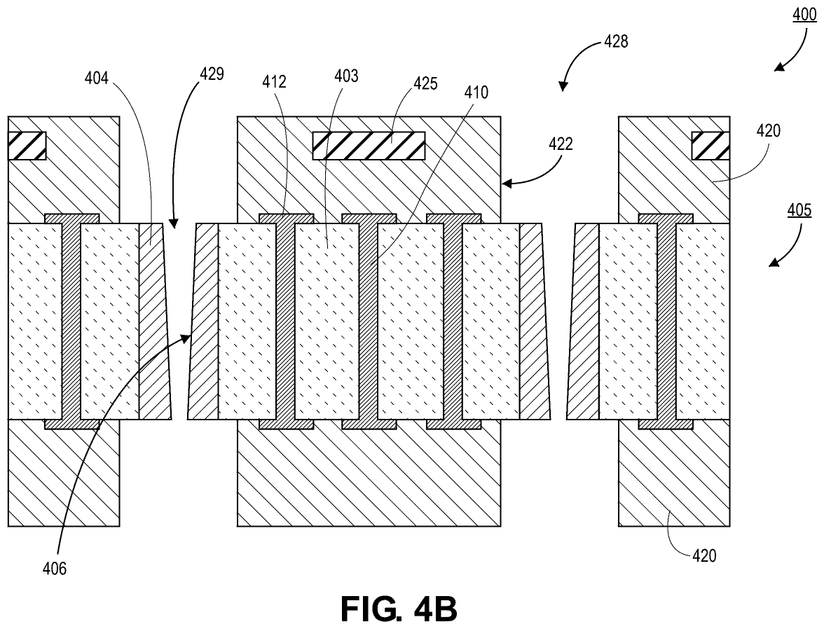

Referring now to FIGS. 4A and 4B, a singulation process of a panel to form package substrate 400 with glass core substrates 405 is shown, in accordance with an additional embodiment. In an embodiment, FIG. 4A is similar to FIG. 3D with the exception of the profile of the sidewall 422 of the opening 428 through the buildup layers 420. For example, the glass core substrate 405 may comprise first regions 403 and second regions 404. Vias 410 with pads 412 may also be provided. In an embodiment, a bridge 425 may be provided in the upper buildup layer 420.

In FIG. 4A, the sidewalls 422 of the openings 428 may have substantially vertical profiles. Such a vertical profile may be the result of a mechanical drilling process or the like. Similar to FIG. 3D, the openings 428 may be aligned over the second regions 404 of the glass core substrate 405. The openings 428 may expose at least a portion of the second regions 404. In some embodiments, the openings 428 may also expose a portion of the first region 403.

Referring now to FIG. 4B, a cross-sectional illustration of the package substrate 400 after openings 429 are formed through the second regions 404 is shown, in accordance with an embodiment. In an embodiment, the openings 429 through the second regions 404 may be formed with a laser ablation process or the like. In the case of a single sided laser ablation, the edge 406 of the second regions 404 may be sloped. Though, the edge 406 may have any suitable profile, such as any of those described herein, depending on the process used to form the openings 429.

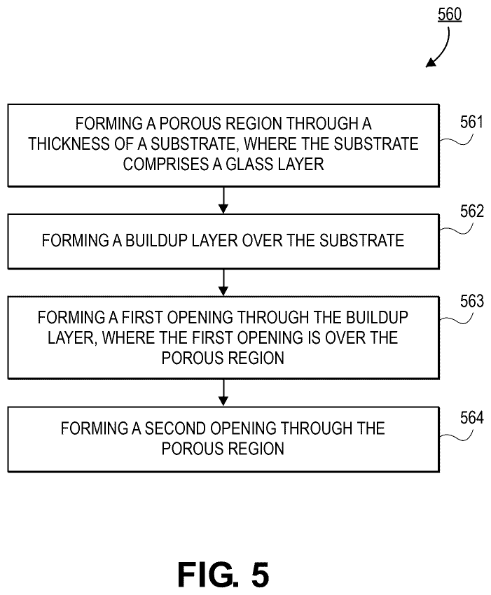

Referring now to FIG. 5, a flow diagram describing a process 560 for singulating a package substrate using selectively formed high porosity regions is shown, in accordance with an embodiment. In an embodiment, the process 560 may be similar to the process described with respect to FIGS. 3A-3E and/or FIGS. 4A and 4B. The resulting package substrate formed from process 560 may be similar to any of the package substrates described in greater detail herein.

In an embodiment, the process 560 may begin with operation 561, which comprises forming a porous region through a thickness of a substrate. In an embodiment, the substrate comprises a glass layer. In an embodiment, the porous region may be formed with a selective wet etching process, such as a wet etching process comprising KOH or NaOH. In an embodiment, the porosity of the porous region may be between 20% and approximately 99%. In an embodiment, an interface between the porous region and the remainder of the substrate may be non-linear (e.g., curved) or the like.

In an embodiment, the process 560 may continue with operation 562, which comprises forming a buildup layer over the substrate. In an embodiment, the buildup layer may comprise a plurality of laminated buildup film layers. Electrical routing, bridges, and/or any other components may be formed within the buildup layer.

In an embodiment, the process 560 may continue with operation 563, which comprises forming a first opening through the buildup layer. In an embodiment, the first opening may be over the porous region. That is, at least a portion of the porous region may be exposed by the first opening.

In an embodiment, the process 560 may continue with operation 564, which comprises forming a second opening through the porous region. In an embodiment, the second opening may be formed with a laser ablation process or the like. Due to the high porosity of the porous region, the laser ablation process induces less damage to the substrate compared to a laser ablation process that passes through a region of the substrate with low porosity. In an embodiment, the laser ablation process may result in the sidewall of the opening being sloped.

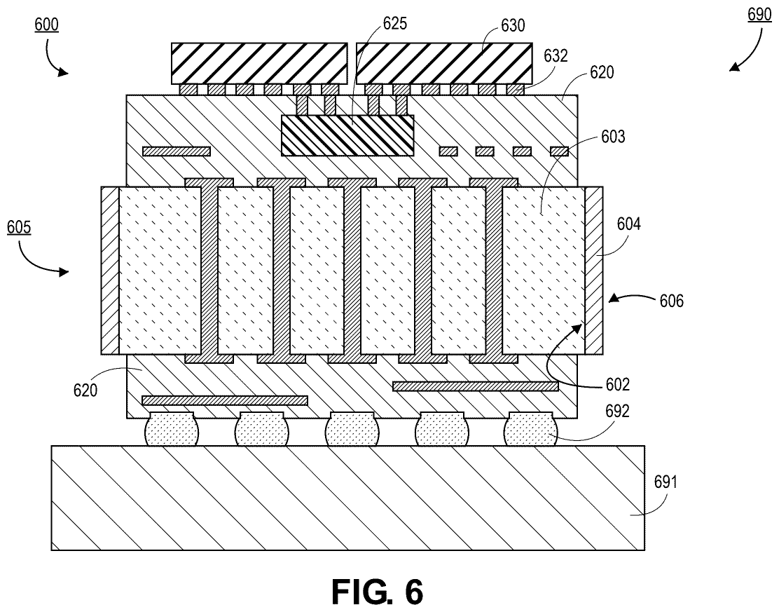

Referring now to FIG. 6, a cross-sectional illustration of an electronic system 690 is shown, in accordance with an embodiment. In an embodiment, the electronic system 690 may comprise a board 691, such as a printed circuit board (PCB), a motherboard, or the like. In an embodiment, the board 691 may be electrically coupled to a package substrate 600 by interconnects 692. The interconnects 692 may comprise solder balls, sockets, pins, or any other suitable SLI architecture.

In an embodiment, the package substrate 600 may be similar to any of the package substrates described in greater detail herein. For example, the package substrate 600 may comprise a glass core substrate 605 between buildup layers 620. In an embodiment, the glass core substrate 605 may comprise a first region 603 with a first porosity and a second region 604 with a second porosity that is higher than the first porosity. The second region 604 may surround the first region 603. In an embodiment, an interface 602 between the first region 603 and the second region 604 may be vertical, sloped, curved, or have any other profile described in greater detail herein. An outer edge 606 of the glass core substrate 605 may be vertical, sloped, or have any other profile described in greater detail herein.

In an embodiment, one or more dies 630 may be electrically coupled to the package substrate 600 through interconnects 632. In an embodiment, the interconnects 632 may comprise solder balls, copper bumps, hybrid bonding interfaces, or any other suitable FLI architecture. In an embodiment, the one or more dies 630 may comprise any type of die, such as processor (e.g., a central processing unit (CPU), a graphics processing unit (GPU), an XPU, etc.), a memory die, a communications die, and/or the like. In some embodiments, a bridge 625 that is embedded in the buildup layer 620 or provided over the buildup layer 620 may electrically couple two dies 630 together. That is, an electrically conductive path may be provided from a first die 630 to a second die 630, and the electrically conductive path may pass through and/or over the bridge 625.

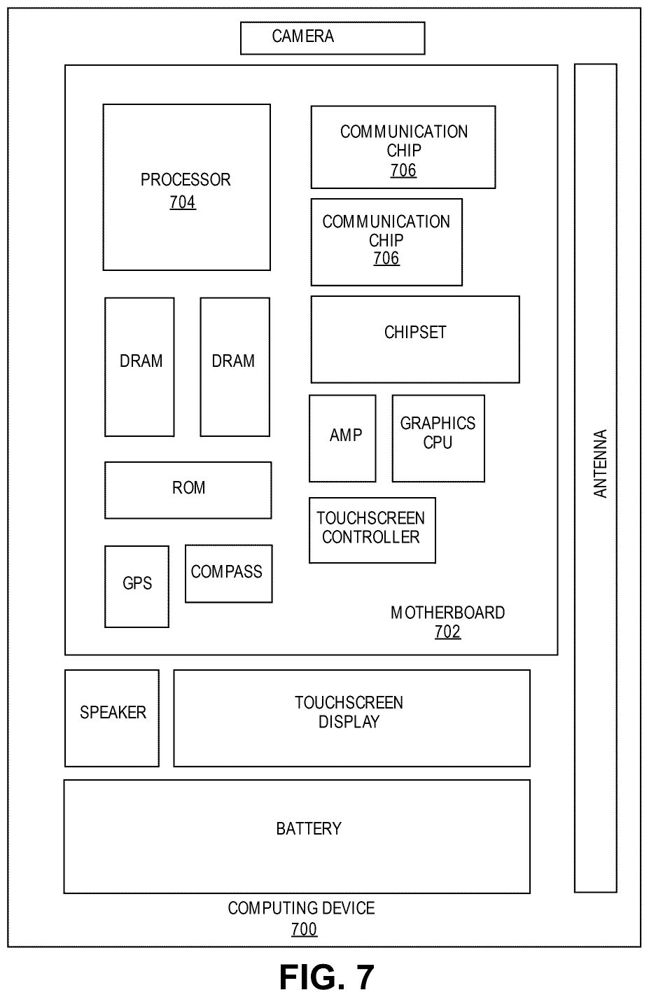

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic package that comprises a package substrate with a glass core that includes a low porosity ring around a perimeter of the glass core, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic package that comprises a package substrate with a glass core that includes a low porosity ring around a perimeter of the glass core, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate that comprises a glass layer, wherein a first region of the substrate has a first porosity and a second region of the substrate has a second porosity that is higher than the first porosity, and wherein the second region is at an edge of the substrate; and a via through a thickness of the substrate.

Example 2: the apparatus of Example 1, wherein the second region is a ring around a perimeter of the substrate.

Example 3: the apparatus of Example 1 or Example 2, wherein the second region extends from a top surface of the substrate to a bottom surface of the substrate.

Example 4: the apparatus of Examples 1-3, wherein the second region has a sidewall profile that is orthogonal to a top surface or a bottom surface of the substrate.

Example 5: the apparatus of Examples 1-4, wherein the second region has a sidewall profile that is non-orthogonal to a top surface or a bottom surface of the substrate.

Example 6: the apparatus of Example 5, wherein the sidewall profile comprises a first slope and a second slope.

Example 7: the apparatus of Examples 1-6, further comprising: a buildup layer over the substrate, wherein an edge of the buildup layer is offset from the edge of the substrate.

Example 8: the apparatus of Example 7, wherein the edge of the buildup layer is non-orthogonal to a top surface or a bottom surface of the substrate.

Example 9: the apparatus of Examples 1-8, wherein the second porosity is at least 30% porous.

Example 10: the apparatus of Examples 1-9, wherein the second region extends from the edge of the substrate into the substrate at least 5.0 μm.

Example 11: an apparatus, comprising: a glass core, wherein the glass core comprises: a first region that comprises a first porosity; and a second region that surrounds a perimeter of the first region, wherein the second region comprises a second porosity that is higher than the first porosity; and a buildup layer over the glass core, wherein the buildup layer has a first width that is narrower than a second width of the glass core.

Example 12: the apparatus of Example 11, wherein the buildup layer has the first width through an entire thickness of the buildup layer.

Example 13: the apparatus of Example 11 or Example 12, wherein the first width of the buildup layer is at a bottom of the buildup layer in contact with the glass core and a third width of the buildup layer is at a top of the buildup layer, wherein the third width is smaller than the first width.

Example 14: the apparatus of Examples 11-13, wherein the second region is a ring at an edge surface of the glass core.

Example 15: the apparatus of Example 14, wherein the edge surface has a vertical profile or a sloped profile.

Example 16: the apparatus of Examples 11-15, wherein the second region extends through an entire thickness of the glass core.

Example 17: the apparatus of Examples 11-16, further comprising: a die electrically coupled to the buildup layer; and a board electrically coupled to the glass core.

Example 18: an apparatus, comprising: a substrate, wherein the substrate comprises: a first glass layer with a first porosity; a second glass layer with a second porosity that is higher than the first porosity, wherein the second glass layer surrounds a perimeter of the first glass layer; and an interface between the first glass layer and the second glass layer that comprises a gradient in porosity from the first porosity to the second porosity; and a buildup layer over the substrate.

Example 19: the apparatus of Example 18, wherein the interface between the first glass layer and the second glass layer is curved.

Example 20: the apparatus of Example 18 or Example 19, wherein an inner edge of the second glass layer is not parallel with an outer edge of the second glass layer.

What is claimed is:

1. An apparatus, comprising:
a substrate that comprises a glass layer, wherein a first region of the substrate has a first porosity and a second region of the substrate has a second porosity that is higher than the first porosity, and wherein the second region is at an edge of the substrate; and
a via through a thickness of the substrate.

2. The apparatus of claim 1, wherein the second region is a ring around a perimeter of the substrate.

3. The apparatus of claim 1, wherein the second region extends from a top surface of the substrate to a bottom surface of the substrate.

4. The apparatus of claim 1, wherein the second region has a sidewall profile that is orthogonal to a top surface or a bottom surface of the substrate.

5. The apparatus of claim 1, wherein the second region has a sidewall profile that is non-orthogonal to a top surface or a bottom surface of the substrate.

6. The apparatus of claim 5, wherein the sidewall profile comprises a first slope and a second slope.

7. The apparatus of claim 1, further comprising:
a buildup layer over the substrate, wherein an edge of the buildup layer is offset from the edge of the substrate.

8. The apparatus of claim 7, wherein the edge of the buildup layer is non-orthogonal to a top surface or a bottom surface of the substrate.

9. The apparatus of claim 1, wherein the second porosity is at least 30% porous.

10. The apparatus of claim 1, wherein the second region extends from the edge of the substrate into the substrate at least 5.0 μm.

11. An apparatus, comprising:
a glass core, wherein the glass core comprises:
a first region that comprises a first porosity; and
a second region that surrounds a perimeter of the first region, wherein the second region comprises a second porosity that is higher than the first porosity; and
a buildup layer over the glass core, wherein the buildup layer has a first width that is narrower than a second width of the glass core.

12. The apparatus of claim 11, wherein the buildup layer has the first width through an entire thickness of the buildup layer.

13. The apparatus of claim 11, wherein the first width of the buildup layer is at a bottom of the buildup layer in contact with the glass core and a third width of the buildup layer is at a top of the buildup layer, wherein the third width is smaller than the first width.

14. The apparatus of claim 11, wherein the second region is a ring at an edge surface of the glass core.

15. The apparatus of claim 14, wherein the edge surface has a vertical profile or a sloped profile.

16. The apparatus of claim 11, wherein the second region extends through an entire thickness of the glass core.

17. The apparatus of claim 11, further comprising:
a die electrically coupled to the buildup layer; and
a board electrically coupled to the glass core.

18. An apparatus, comprising:
a substrate, wherein the substrate comprises:
a first glass layer with a first porosity;
a second glass layer with a second porosity that is higher than the first porosity, wherein the second glass layer surrounds a perimeter of the first glass layer; and
an interface between the first glass layer and the second glass layer that comprises a gradient in porosity from the first porosity to the second porosity; and
a buildup layer over the substrate.

19. The apparatus of claim 18, wherein the interface between the first glass layer and the second glass layer is curved.

20. The apparatus of claim 18, wherein an inner edge of the second glass layer is not parallel with an outer edge of the second glass layer.
